(19) United States
(12) Patent Application Publication
(10) Pub. No.: US 2025/0321327 A1
(43) Pub. Date: Oct. 16, 2025

(54) LIDAR SYSTEM USING MULTIPLE WAVELENGTHS AND OPERATING METHOD THEREOF

(71) Applicant: SAMSUNG ELECTRONICS CO., LTD., Suwon-si (KR)

(72) Inventors: Sangyun PARK, Suwon-si (KR); Byunghoon Ko, Suwon-si (KR); Seungwoo Noh, Suwon-si (KR); Jinwoo Choi, Suwon-si (KR); Minkyung Lee, Suwon-si (KR); Jangwoo You, Suwon-si (KR)

(73) Assignee: SAMSUNG ELECTRONICS CO., LTD., Suwon-si (KR)

(21) Appl. No.: 19/013,517

(22) Filed: Jan. 8, 2025

(30) Foreign Application Priority Data
Apr. 12, 2024 (KR) 10-2024-0049410

(51) Int. Cl. G01S 7/4914; G01S 7/4912; G01S 7/493; G01S 17/34; G01S 17/58; G01S 17/931

(52) U.S. Cl. CPC G01S 7/4914; G01S 7/4917; G01S 7/493; G01S 17/34; G01S 17/58; G01S 17/931

(57) ABSTRACT

Provided is a light detection and ranging (LiDAR) system including an optical coupler that generates an optical signal by mixing a transmission signal with a reception signal, in which the transmission signal is reflected back from a target, a photodiode that converts the optical signal into an analog beating signal, and a band pass filter array that filters the analog beating signal to extract a beating frequency.

### CROSS-REFERENCE TO RELATED APPLICATION

This application is based on and claims priority under 35 U.S.C. § 119 to Korean Patent Application No. 10-2024-0049410, filed on Apr. 12, 2024, in the Korean Intellectual Property Office, the disclosures of which are incorporated by reference herein in their entireties.

### BACKGROUND

### 1. Field

The disclosure relates to a light detection and ranging (LiDAR) system and an operating method thereof.

### 2. Description of the Related Art

A frequency modulated continuous wave (FMCW) LIDAR device transmits a frequency modulation signal in the form of a triangular wave over time.

The LiDAR device may require a wide chirp bandwidth to achieve high distance resolution. For example, a bandwidth of approximately 1.5 GHZ may be needed to attain a distance resolution of 10 cm. To accurately acquire information in a frequency range without loss, binarization may be performed at a rate at least twice the bandwidth, meaning the analog-to-digital converters need to operate at a minimum of 3 GHZ. Additionally, a digital system of the LiDAR device may need to process and convert large volumes of data (e.g., 3 gigabytes of sampling per second) from a time domain to a frequency domain, which poses challenges due to the significant computing resources required.

### SUMMARY

One or more embodiments of the present disclosure provide a method and an apparatus for reducing computing resources required for performing frequency analysis on a beat signal by analyzing frequencies in an analog state, prior to converting the beating signal to a digital signal in beating signal analysis.

According to an aspect of the present disclosure, a light detection and ranging (LIDAR) system may include: an optical coupler configured to generate an optical signal by mixing a transmission signal with a reception signal, in which the transmission signal is reflected back from a target; a photodiode configured to convert the optical signal into an analog beating signal; and a band pass filter array configured to filter the analog beating signal to extract a beating frequency.

The LiDAR system may further include a control circuit configured to calculate at least one of a distance to the target and a speed of the target based on the beating frequency.

The LiDAR system may further include an analog-to-digital converter configured to convert the filtered analog beating signal into a digital signal by sampling and quantizing the filtered beating signal.

The band pass filter array includes a plurality of band pass filters having different pass bands.

The band pass filter array is configured to have a preset frequency search range for extracting the beating frequency, wherein the frequency search range is divided into a preset number of frequency levels based on a measurable distance and a distance resolution, and when the number of band pass filters is n, the number of frequency levels is determined to be n.

The band pass filter array includes the plurality of band pass filters connected in parallel with each other.

The plurality of band pass filters are electric circuits including a series and parallel combination of a resistor, an inductor, and a capacitor.

The band pass filter array includes a plurality of band pass filter groups. Each of the plurality of band pass filter groups has a plurality of pass bands repeated at a preset period.

The band pass filter array may have a preset frequency search range for extracting the beating frequency. The frequency search range is divided into a preset number of frequency levels based on a measurable distance and a distance resolution, and when the number of band pass filter groups is n, the number of frequency levels is determined to be 2ⁿ.

The band pass filter array may include the plurality of band pass filter groups connected in parallel with each other. Each of the plurality of band pass filter groups may include a plurality of band pass filters connected in parallel with each other.

The plurality of band pass filters are electric circuits including a series and parallel combination of a resistor, an inductor, and a capacitor.

The band pass filter array includes a plurality of band pass filters. Each of the plurality of band pass filters has a plurality of pass bands repeated at a preset period, and has a preset frequency search range for extracting the beating frequency. The frequency search range is divided into a preset number of frequency levels based on a measurable distance and a distance resolution.

Each of the plurality of band pass filters may include a surface acoustic wave filter including an input transducer and an output transducer, the input transducer may include a plurality of pairs of first transducer electrodes and second transducer electrodes, each of the first transducer electrodes may include a plurality of first group lines extending radially in a first direction, and each of the second transducer electrodes may include a plurality of second group lines extending counter-radially in a second direction and alternately arranged with the first group lines, the output transducer may include a plurality of pairs of third transducer electrodes and fourth transducer electrodes, and each of the third transducer electrodes includes a plurality of third group lines extending radially in the first direction, and each of the fourth transducer electrodes may include a plurality of fourth group lines extending counter radially in the second direction and alternately arranged with the third group lines.

A gap between the first group lines and the second group lines increases in the first direction, and a gap between the third group lines and the fourth group lines increases in the first direction.

Widths of the first group lines and the third group lines increase in the first direction, and widths of the second group lines and the fourth group lines decrease toward the second direction.

A distance of each of the input transducer and the output transducer in the first direction corresponds to the frequency search range, and when the number of frequency levels is m, the number of pairs of the first transducer electrodes and the second transducer electrodes is m/2.

The pairs of the first transducer electrodes and the second transducer electrodes are formed only in odd-numbered equal division areas when a length of each of the input transducer and the output transducer in the first direction is equally divided into 2^{p}, where p is a natural number.

The pairs of the first transducer electrodes and the second transducer electrodes are formed only in a division area equally divided into 2^{p}−1 when a length of each of the input transducer and the output transducer in the first direction is equally divided into 2^{p}, where p is a natural number.

According to another aspect of the present application, an operating method of a light detection and ranging (LiDAR) system may include: generating an optical signal by mixing a transmission signal with a reception signal, in which the transmission signal is reflected back from a target; converting the optical signal into an analog beating signal; extracting, by a band pass filter array, a beating frequency by filtering the analog beating signal; and calculating at least one of a distance to the target and a speed of the target based on the beating frequency.

A vehicle including: an optical coupler configured to obtain an optical signal by mixing a transmission signal to be transmitted to a target, with a reception signal that is received when the transmission signal is reflected back from the target; a focal plane array configured to convert the optical signal into an analog beating signal; and a plurality of band pass filters configured to receive the analog beating signal and pass a plurality of different frequency bands of the analog beating signal to extract a beating frequency from at least one of the plurality of different frequency bands.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a graph showing a transmission signal transmitted from an FMCW LIDAR and a reception signal at which the transmission signal is reflected and incident from a target, and a beat frequency;

FIG. 2 is a conceptual diagram illustrating a LiDAR system according to one or more embodiment;

FIG. 3 is a diagram illustrating pixels included in a focal plane array;

FIG. 4 is a block diagram illustrating a control circuit according to one or more embodiment;

FIG. 5 is a diagram for describing a frequency analysis method according to one or more embodiment;

FIG. 6 is a circuit diagram of a band pass filter according to one or more embodiment;

FIG. 7 is a diagram for describing a frequency analysis method according to one or more embodiment;

FIG. 8 is a circuit diagram of a band pass filter group according to one or more embodiment;

FIG. 9 is a schematic view for describing a surface acoustic wave filter;

FIG. 10 is a diagram for describing a frequency analysis method using a surface acoustic wave filter;

FIG. 11A is an enlarged view of a first region of FIG. 10, and FIG. 11B is an enlarged view of a second region of FIG. 10;

FIG. 12 is a diagram for describing a frequency analysis method according to one or more embodiment;

FIG. 13 is an enlarged view of a third region of FIG. 12;

FIG. 14 is a flowchart for describing a frequency analysis method according to one or more embodiment;

FIG. 15 is a perspective view showing an electronic device to which a LiDAR system according to one or more embodiment is applied; and

FIGS. 16 and 17 are respectively conceptual side and top views illustrating a case in which a LiDAR system according to one or more embodiment is applied to a vehicle.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

While such terms as “first,” “second,” etc., may be used to describe various elements, such elements must not be limited to the above terms. The above terms may be used only to distinguish one element from another.

The terms used in the present embodiments have selected the currently widely used general terms possible in consideration of their functions in the present embodiments, but this may vary depending on the intention or precedent of a technician in the art, the emergence of a new technology, and the like. In addition, in certain cases, there are arbitrarily selected terms, and in this case, the meaning will be described in detail in the description part of the embodiment. Therefore, the terms used in the present embodiments should not be defined simply as the names of the terms, but should be defined based on the meanings of the terms and the overall content of the present embodiments.

In the descriptions of embodiments, when a part is connected to another part, it includes not only a case of being directly connected, but also a case of being electrically connected with another component therebetween. In addition, when a part “includes” a component, the part may further include other components, not excluding other components unless otherwise stated.

Terms such as “consists of”, “includes”, or the like used in the present embodiments should not be construed as necessarily including all of the various components or steps described in the specification, and it should be construed that some of the components or some steps may not be included, or additional components or steps may be included.

The description of the following embodiments should not be construed as limiting the scope of rights, and what those skilled in the art may easily infer should be construed as belonging to the scope of rights of the embodiments. Hereinafter, embodiments solely for illustration will be described in detail with reference to the accompanying drawings.

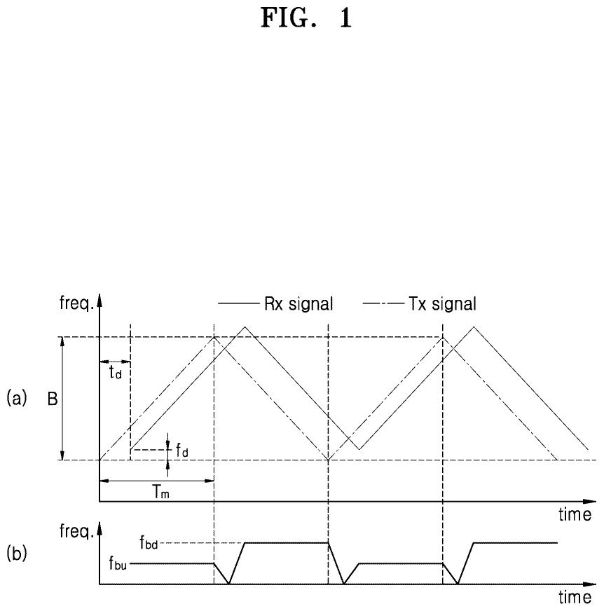

FIG. 1 illustrates graphs showing a transmission signal transmitted from an FMCW LIDAR device and a reception signal in which the transmission signal is reflected and incident from a target, and a beat frequency.

Graph (a) of FIG. 1 shows a transmission signal (Tx signal) transmitted from the FMCW LiDAR device and a reception signal (Rx signal) in which the transmission signal is reflected and incident from a target. There are a time difference corresponding to a delay time (td) and a frequency difference corresponding to the Doppler frequency (fd) between the transmission signal (Tx signal) and the reception signal shown (Rx signal). In Graph (a) of FIG. 1, B denotes a modulation bandwidth and Tm denotes a modulation period.

Graph (b) of FIG. 1 illustrates a beat frequency expressed as a frequency difference between a transmission signal (Tx signal) and a reception signal (Rx signal). In addition, fbu means an up-beat frequency corresponding to an up chirp, and fbd means a down-beat frequency corresponding to a down chirp.

The up-beat frequency and down-beat frequency include frequency shifts components due to the distance to a moving object and a relative speed thereof. These are referred to as a beat frequency (fb) and a Doppler frequency (fd), respectively.

The up-beat frequency fbu and the down-beat frequency fbd may be expressed according to Equations 1 and 2 below.

fbu=fb−fd [Equation 1]

fbd=fb+fd [Equation 2]

A positive Doppler frequency means that the moving object is approaching the LiDAR, and a negative Doppler frequency means that the moving object is moving away from the LiDAR. Therefore, the distance between a moving object and the LIDAR may be obtained as the average of the up-beat frequency fbu and the down-beat frequency fbd, and the moving speed of the moving object may be calculated using the Doppler frequency fd.

The up-beat frequency fbu and down-beat frequency fbd may be obtained by converting received analog beating signals into digital signals by sampling and quantizing the received analog beating signal by an analog-to-digital converter, and then performing a Fast Fourier Transform (FFT) on the digital signals.

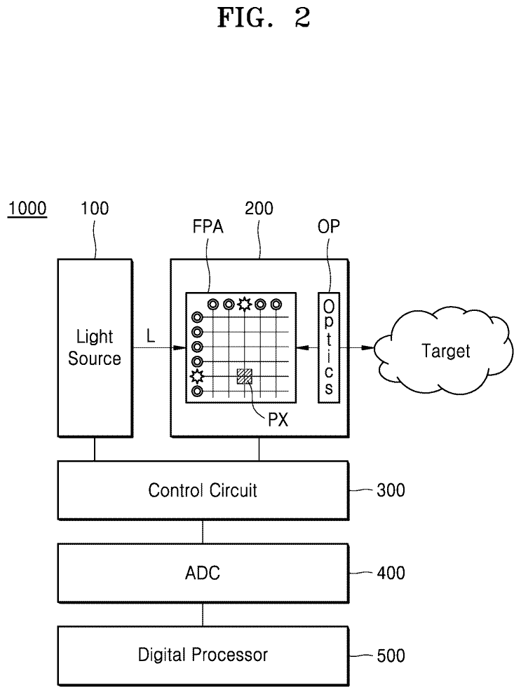

FIG. 2 is a conceptual diagram illustrating a LIDAR system according to one or more embodiment.

Referring to FIG. 2, a LiDAR system 1000 may include a light source 100, a transceiver 200, a control circuit 300, an analog-to-digital converter (ADC) 400, and a digital processor 500. The light source 100, the transceiver 200, and the control circuit 300 may be integrated into a single chip (or a semiconductor optical element).

According to one or more embodiment, the light source 110 may generate light L having an operating wavelength (e.g., a wavelength of an electromagnetic spectrum). In this case, the light L may be referred to as a transmission signal, an optical signal, a laser beam, a light beam, an optical beam, an emitted beam, an emitted light, or simply a beam. The light source 100 may further include an optical modulator for modulating light.

For FMCW driving, the optical modulator (or light source 100) may perform frequency modulation (or chirping) as shown in FIG. 1 around an operating wavelength. In this case, the bandwidth of frequency modulation (or chirping) determines a depth resolution. For example, for a 10 cm distance resolution, frequency modulation (or chirping) should occur in a bandwidth of about 1.5 GHZ. The implementation method of this frequency modulation (or chirping) may be either open-loop control or closed-loop control, and pre-distortion may be performed based on information obtained through pre-calibration to improve linearity characteristics.

The optical modulator may modulate light in various ways. For example, the optical modulator may serve to modulate the phase of light. Specifically, the optical modulator may serve to modulate the amplitude of light. Alternatively or additionally, the optical modulator may serve to simultaneously modulate the phase and amplitude of light. In addition, the optical modulation function of the optical modulator may be variously changed. Meanwhile, the optical modulator may perform optical modulation by an electrical method, or may perform optical modulation by various methods such as a magnetic method, a thermal method, and a mechanical method. As a specific example, the optical modulator may include at least one phase shifter or phase shifting element, and the phase shifter may include, for example, at least one or more elements selected from a group consisting of a gain element, an all-pass filter, a Bragg grating, a dispersion material element, a wavelength tuning element, and a phase tuning element. In addition, an actuation mechanism applied to the optical modulator may include at least one selected from a group consisting of, for example, thermo-optic actuation, electro-optic actuation, electroabsorption actuation, free carrier absorption actuation, magneto-optic actuation, liquid crystal actuation, and all-optical actuation. This actuation mechanism may be related to the phase tuning described above. However, the configuration and actuation mechanism of the phase shifter described in detail here is only an example, and embodiments are not limited thereto.

According to one or more embodiment, the transceiver 200 may include a focal plane array FPA in which a plurality of pixels PX are arranged in a matrix form and an optics OP for controlling an emission angle.

The transceiver 200 may be functionally or structurally divided into a transmission unit (e.g., a transceiver) and a reception unit (e.g., a receiver).

In the transmission unit, pixels are arranged in at least one of at least x and y axes to constitute a focal plane array (FPA). In addition, the transmission unit may emit light L as a transmission signal from one pixel PX included in the focal plane array FPA.

According to one or more embodiment, when the optics OP emits light L from a pixel PX to a free space, the optics OP may control a light emission angle. For example, the optics OP may include a prism, a micro prism array, a diffraction grating, and the like.

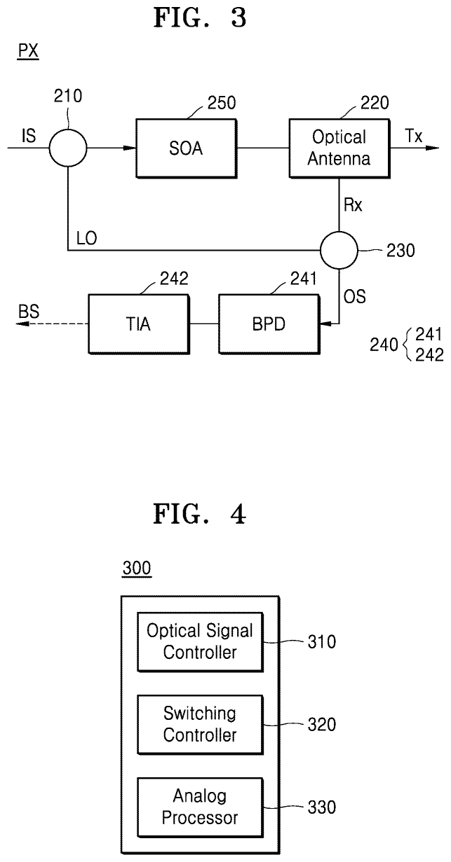

The reception unit may mix a transmission signal with a reception signal in which the transmission signal is reflected and incident from a target and convert the mixed signal into an electrical signal. The electrical signal may be referred to as beating signal including beating frequency information. For example, the reception unit may be implemented to be incident on a balanced photodiode 241 after 50:50 coupling using a second optical coupler 230 of FIG. 3 to be described later. However, the coupling method is not limited thereto, and may be implemented using, for example, a beam splitter or the like. Regardless of a specific mixing implementation method, the signal obtained from the reception unit may include beating frequency information for light. The light contains distance and/or speed information for the target and is reflected in the beating frequency.

The control circuit 300 may be connected to the light source 100 and the transceiver 200 and control operations thereof. For example, before converting the beating signal BS into a digital signal, the control circuit 300 may convert the beating signal BS into distance and/or speed information for the target to analyze the frequency in an analog signal state.

FIG. 3 is a diagram illustrating pixels included in a focal plane array.

Referring to FIG. 3, the pixel PX may divide an input signal IS (or the light L of FIG. 2) into a local oscillator signal LO and a transmission signal Tx, couple the transmission signal Tx to the free space, couple the reception signal Rx to the pixel PX again, and mix the local oscillator signal LO with the reception signal Rx.

The pixel PX according to one or more embodiment may include a first optical coupler 210, an optical antenna 220, a second optical coupler 230, and a photoelectric converter 240. The pixel PX may receive light (light L of FIG. 2) as an input signal IS. The first optical coupler 210 may be arranged between an input terminal and the optical antenna 220. The first optical coupler 210 may divide an input signal IS received from the input terminal into a local oscillator signal LO and a transmission signal Tx. The optical antenna 220 may receive a reception signal Rx reflected by a target.

The optical antenna 220 is a device that emits light from an on-chip waveguide to a free space and/or couples light from the free space to the on-chip waveguide. The optical antenna 220 may be implemented as a grating coupler, an edge coupler, an integrated reflector, or any spot size converter. The optical antenna 220 may be sensitive to polarization with much higher emission/coupling efficiency for light with one specific polarization (e.g., transverse electricity (TE) or transverse magnetic (TM). The optical antenna 220 may be mutual and thus collect a reception signal Rx from a target (e.g., an object in an environment). The optical antenna 220 may provide the reception signal Rx to the second optical coupler 230. Although FIG. 3 illustrates a co-axial implementation method in which light emission and collection are performed through the same optical antenna 220, bi-axial implementation in which light emission and collection are performed separately using each optical antenna is also possible.

The second optical coupler 230 may generate an output signal OS by mixing the reception signal Rx with the local oscillator signal LO divided and provided by the first optical coupler 210. The second optical coupler 230 may be a balanced 2×2 optical mixer.

The pixel PX may include a photoelectric converter 240 that converts an output signal OS, which is an optical signal, into an electrical signal. The photoelectric converter 240 may include a balanced photodiode (BPD) 241 configured to convert an optical signal into an electrical signal for detecting a beating frequency, and a transimpedance amplifier (TIA) that amplifies the intensity of the electrical signal generated by the balanced photodiode 241. For example, the transimpedance amplifier TIA may amplify the current generated by the balanced photodiode 241 and convert the amplified current into a voltage. The electrical signal BS provided by the trans-impedance amplifier TIA may be provided to the control circuit 300 (see FIG. 2).

The pixel PX according to one or more embodiment may further include an optical amplifier 250 arranged between the first optical coupler 210 and the optical antenna 220 to compensate for light loss. For example, the optical amplifier 250 may be a semiconductor optical amplifier (SOA), and may serve to amplify the optical signal so that the light generated by the light source (see 110 in FIG. 2) may maintain its intensity in the optical antenna 220. Alternatively or additionally, the optical amplifier 250 may serve to increase a signal-to-noise ratio (SNR).

FIG. 4 is a block diagram illustrating a control circuit according to one or more embodiment.

Referring to FIG. 4, the control circuit 300 may include an optical signal controller 310, a switching controller 320, and an analog processor 330.

The optical signal controller 310 may control frequency modulation (or chirping) of the light source 100 described above, which may include a feedback circuit such as a phase-locked loop (PLL).

The switching controller 320 may control switching of the focal plane array FPA of at least one axis of the transmission unit of the transceiver 200. In this case, the switching control may be a manipulation of an optical micro-electromechanical system (MEMS) portion. In addition, this control may be a heating (or thermal) control for a thermodynamic element that manipulates the phase of a micro ring resonator, a mach-zender interferometer, etc. In addition, this control may be a control for electro-optical modulation according to carrier concentration control.

The analog processor 330 may frequency-analyze the analog electrical signal obtained from the reception unit of the transceiver 200 as it is and convert the analog electrical signal into distance and/or speed information with respect to the target.

A conventional LiDAR system may binarize an analog electrical signal through an analog-to-digital converter, convert the binarized analog electrical signal into frequency domain information through Fast Fourier Transform in a digital processor, and then convert the frequency domain information into distance and/or speed information with respect to the target. To achieve a high distance resolution, the conventional LiDAR system may need to convert a large amount of data from the time domain to the frequency domain, which may require considerable computing resources.

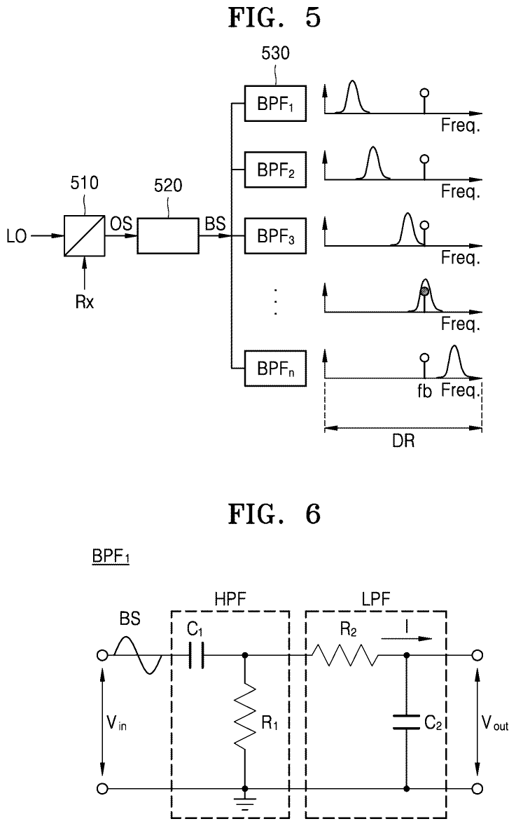

Hereinafter, with reference to FIGS. 5 to 13, a method of directly analyzing frequencies using a band pass filter before converting an analog beating signal into a digital signal by an analog-to-digital converter will be described in detail.

FIG. 5 is a diagram for describing a frequency analysis method according to one or more embodiment. FIG. 6 is a circuit diagram of a band pass filter according to one or more embodiment.

Referring to FIG. 5, the LiDAR system 1000 according to one or more embodiment may include an optical coupler 510, a photodiode 520, and a band pass filter array 530 to analyze the frequency in an analog signal state before converting the beating signal BS into a digital signal.

In this case, the optical coupler 510 of FIG. 5 may correspond to the second optical coupler 230 of FIG. 3, and the photodiode 520 of FIG. 5 may correspond to the balanced photodiode 241 of FIG. 3. In addition, in FIG. 5, for convenience of explanation, the transimpedance amplifier TIA of FIG. 3 is omitted between the photodiode 520 and the band pass filter array 530.

The optical coupler 510 may generate an optical signal (or the output signal OS of FIG. 3) by mixing the local oscillator signal LO with the reception signal Rx in which the local oscillator signal LO is reflected and returned from a target. The photodiode 520 may convert an optical signal (or the output signal OS of FIG. 3) into a beating signal BS. The beating signal BS may be an analog electrical signal.

The band pass filter array 530 may filter the beating signal BS to extract a beating frequency fb. The band pass filter array 530 may include a plurality of band pass filters BPF1, BPF2, BPF3, . . . , and BPFn having different pass bands. The plurality of band pass filters BPF1, BPF2, BPF3, . . . , and BPFn may be connected in parallel with each other.

According to one or more embodiment, each of the band pass filters BPF1, BPF2, BPF3, and steamed BPF1, BPF2, BPF3, . . . , and BPFn may include any one of an electrical circuit consisting of a series and/or parallel combination of resistor (R), inductor (L), and capacitor (C) elements, a surface acoustic wave filter, and a volume acoustic wave filter.

For example, referring to FIG. 6, the band pass filter (e.g., BPF1) may be an electrical circuit including a series and/or parallel combination of resistors R1 and R2 and capacitors C1 and C2. The band pass filter (e.g., BPF1) is a combination of a high-pass filter unit HPF including a first capacitor C1 and a first resistor R1, and a low-pass filter unit LPF including a second capacitor C2 and a second resistor R2, allowing a specific band frequency, and attenuating a signal having a frequency higher or lower than a cutoff frequency to form a band pass filter. However, the electrical circuit of the band pass filter illustrated in FIG. 6 is only an example, and is not limited thereto.

The band pass filter array 530 has a preset frequency search range DR for extracting the beating frequency fb, and the frequency search range DR may be divided into a preset number of frequency levels based on measurable distance and distance resolution.

For example, in order for the LiDAR system 1000 to implement a measurable distance of 200 m and a distance resolution of 10 cm, about 2000 levels of distance component analysis corresponding to the value of 200 m divided by 10 cm may be required, and thus, about 2000 band pass filters may be required. In other words, when the number of band pass filters BPF1, BPF2, BPF3, . . . , and BPFn is n, the number of frequency levels may be determined to be n.

According to one or more embodiment, the LiDAR system 1000 may further include an analog-to-digital converter 400 that converts the filtered beating signal BS into a digital signal by sampling and quantizing the filtered beating signal BS. For example, when the beating signals BS passing through each of the band pass filters BPF1, BPF2, BPF3, . . . , and BPFn are processed with a rectifier and an analog-to-digital converter, the power (or intensity) of the beating signal BS in each frequency band may be implemented to be quantified to improve the accuracy of detection of the beat frequency fb.

The control circuit 300 of FIG. 2 (or the analog processor 330 of FIG. 4) may calculate the distance and/or speed with respect to the target based on the extracted beating frequency fb. In this way, by directly detecting the beating frequency fb in the analog signal state, the binarization process and the fast Fourier transform process of converting from the time domain to the frequency domain may be omitted, and thus, the effect of improving computational processing speed and reducing computing resources may be expected.

According to one or more embodiment, each of the band pass filters BPF1, BPF2, BPF3, . . . , and BPFn may be configured as a surface acoustic wave filter.

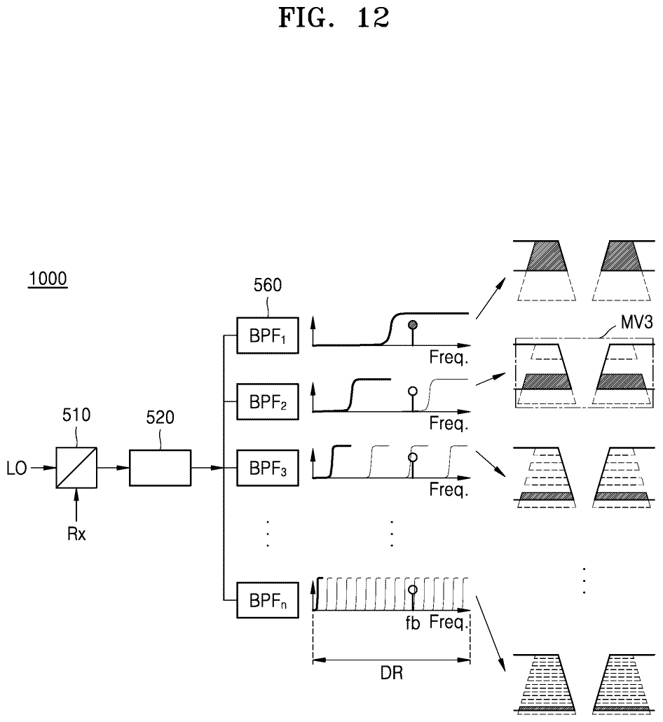

For example, referring to FIG. 5 and FIG. 12 to be described later, the first band pass filter BPF1 of FIG. 5 may be formed like a transducer electrode pair (i.e., a hatched region) of the surface acoustic wave filter shown in the n-th band pass filter BPFn of FIG. 12, and the n-th band pass filter BPFn of FIG. 5 may be formed in a first dotted line region of a plurality of transducer electrode pairs indicated by the dotted line shown in the n-th band pass filter BPFn of FIG. 12. That is, a place where the distance between the transducer electrode pairs is wide may correspond to a low frequency band pass filter, and a place where the distance between the transducer electrode pairs is narrow may correspond to a high frequency band pass filter.

Hereinafter, other embodiments will be described. In the following embodiments, the same components as those of the embodiment described above will be omitted or simplified, and differences will be mainly described.

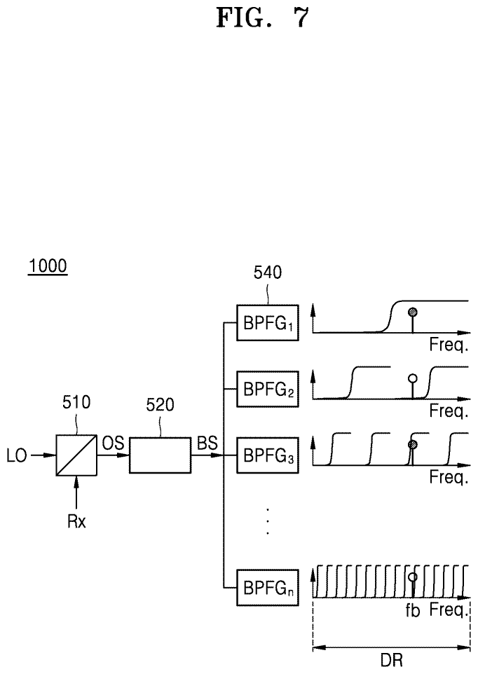

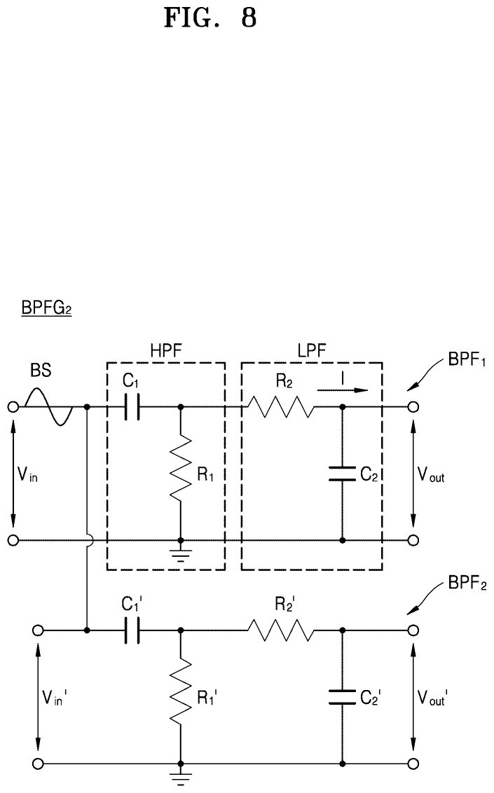

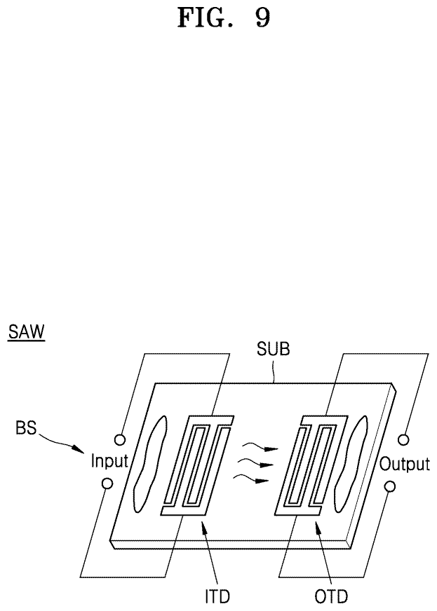

FIG. 7 is a diagram for describing a frequency analysis method according to one or more embodiment. FIG. 8 is a circuit diagram of a band pass filter group according to one or more embodiment.

One or more embodiment illustrated in FIG. 7 is different from one or more embodiment illustrated in FIG. 5 in that the band pass filter array 540 of FIG. 7 including a plurality of band pass filter groups BPFG1, BPFG2, BPFG3, . . . , and BPFGn each including at least one of a plurality of band pass filters BPFG1, BPFG2, BPFG3, . . . , and BPFGn, is different from the band pass filter array 530 of FIG. 5 including a plurality of band pass filter groups BPF1, BPF2, BPF3, . . . , and BPFn, but the other components in FIG. 7 are substantially the same as those illustrated in FIG. 5.

Referring to FIG. 7, the LiDAR system 1000 according to one or more embodiment may include an optical coupler 510, a photodiode 520, and a band pass filter array 540 to analyze the frequency in an analog signal state before converting the beating signal BS into a digital signal.

In this case, the optical coupler 510 of FIG. 7 may correspond to the second optical coupler 230 of FIG. 3, and the photodiode 520 of FIG. 7 may correspond to the balanced photodiode 241 of FIG. 3. In addition, in FIG. 7, for convenience of explanation, the transimpedance amplifier TIA of FIG. 3 is omitted between the photodiode 520 and the band pass filter array 540.

The optical coupler 510 may generate an optical signal (or the output signal OS of FIG. 3) by mixing the local oscillator signal LO with the reception signal Rx in which the local oscillator signal LO is reflected and returned from a target. The photodiode 520 may convert an optical signal (or the output signal OS of FIG. 3) into a beating signal BS. The beating signal BS may be an analog electrical signal.

The band pass filter array 540 may filter the beating signal BS to extract a beating frequency fb. The band pass filter array 540 may include a plurality of band pass filter groups BPFG1, BPFG2, BPFG3, . . . , and BPFGn, each having a plurality of pass bands that are repeated at a preset period.

The repetition period of the pass band of each of the band pass filter groups BPFG1, BPFG2, BPFG3, . . . , and BPFGn may be different. According to one or more embodiment, a period of the pass band of the n-th band pass filter group BPFGn may be DR/²^{ⁿ⁻¹}. For example, the period of the pass band of the first band pass filter group BPFG1 may be DR, the period of the pass band of the second band pass filter group BPFG2 may be DR/2, and the period of the pass band of the third band pass filter group BPFG3 may be DR/4.

The band pass filter array 540 may include a plurality of band pass filter groups BPFG1, BPFG2, BPFG3, . . . , and BPFGn connected in parallel with each other. Each of the band pass filter groups BPFG1, BPFG2, BPFG3, . . . , and BPFGn may include a plurality of band pass filters connected in parallel with each other.

According to one or more embodiment, each of the band pass filters may be configured as an electrical circuit including a series and/or parallel combination of R, L, and C elements.

For example, referring to FIG. 8, the second band pass filter group BPFG2 may include the first band pass filter BPF1 and the second band pass filter BPF2 connected in parallel with each other. The first band pass filter (e.g., BPF1) may be an electrical circuit including a series and/or parallel combination of resistors R1 and R2 and capacitors C1 and C2. In addition, the second band pass filter (e.g., BPF2) may be an electrical circuit including a series and/or parallel combination of resistors R1′ and R2′ and capacitors C1′ and C2′. In this case, values of resistors and capacitors constituting band pass filters included in each of the plurality of band pass filter groups BPFG1, BPFG2, BPFG3, . . . , and BPFGn may be determined according to corresponding pass band cycles. The band pass filter (e.g., BPF1) is a combination of a high-pass filter unit HPF including a first capacitor C1 and a first resistor R1, and a low-pass filter unit LPF including a second capacitor C2 and a second resistor R2, allowing a specific band frequency, and attenuating a signal having a frequency higher or lower than a cutoff frequency to form a band pass filter. However, the electrical circuit of the band pass filter illustrated in FIG. 8 is only an example, and is not limited thereto.

The band pass filter array 540 has a preset frequency search range DR for extracting the beating frequency fb, and the frequency search range DR may be divided into a preset number of frequency levels based on measurable distance and distance resolution.

For example, as described above, in order for the LiDAR system 1000 to implement a measurable distance of 200 m and a distance resolution of 10 cm, about 2000 levels of distance component analysis corresponding to the value of 200 m divided by 10 cm may be required.

Unlike the frequency analysis method shown in FIG. 5, in the frequency analysis method shown in FIG. 7, the pass band of each band pass filter reflects each bit in the binarized value of the beating signal. For example, in a simple example provided with only the first pass band filter (BPF1) and the second pass band filter (BPF2) of FIG. 8, if the beating signal linearly increases in the direction from the lowest to the highest for the entire frequency search range DR, whether the first pass band filter (BPF1) passes and whether the second pass band filter (BPF2) passes may be confirmed and expressed as (0,0), (0,1), (1,0), and (1,1). That is, the pass signal of the first pass band filter BPF1 represents a 2-bit signal representing the least significant bit, and the pass signal of the second pass band filter BPF2 represents a 2-bit signal representing the most significant bit. (to WC: please check)

In other words, when the number of band pass filter groups BPFG1, BPFG2, BPFG3, . . . , and BPFGn is n, the number of frequency levels may be determined to be 2ⁿ. Therefore, 11 band pass filter groups BPFG1, BPFG2, BPFG3, . . . , and BPFGn may be required for distance component analysis of 2000 levels.

According to one or more embodiment, the LiDAR system 1000 may further include an analog-to-digital converter 400 that converts the filtered beating signal BS into a digital signal by sampling and quantizing the filtered beating signal BS. For example, when the beating signals BS passing through each of the band pass filters BPF1, BPF2, BPF3, . . . , and BPFn are processed with a rectifier and an analog-to-digital converter, the power (or intensity) of the beating signal BS in each frequency band may be implemented to be quantified to improve the accuracy of detection of the beat frequency fb.

In addition, the LiDAR system 1000 may need information on the size itself of the detected beating signal (or the frequency corresponding to noise) in addition to a main frequency (or frequency corresponding to the target of interest) of the beating signal. This may utilize the magnitude of the beating signal quantified by directly rectifying and binarizing the output signal of the photodiode 520 before filtering the band pass filter array 540. In this case, the size of the beating signal may be used to determine the presence or absence of a target object (or target) through a thresholding process that creates a binary image.

Meanwhile, when an error occurs in a limited number of pixels, the LIDAR system 1000 of the disclosure may include, in a digital system, an image processing algorithm that corrects such an error. Alternatively, errors may be corrected using error correction techniques known in the field of cameras and radars.

The control circuit 300 of FIG. 2 (or the analog processor 330 of FIG. 4) may calculate the distance and/or speed with respect to the target based on the extracted beating frequency fb. In this way, by directly detecting the beating frequency fb in the analog signal state, the binarization process and the fast Fourier transform process of converting from the time domain to the frequency domain may be omitted, and thus, the effect of improving computational processing speed and reducing computing resources may be expected. In addition, in the case of the embodiment shown in FIG. 7 compared to the embodiment shown in FIG. 5, the number of band pass filters required to implement the same distance resolution may be reduced, and miniaturization and cost reduction effects may be expected when manufacturing the LIDAR system.

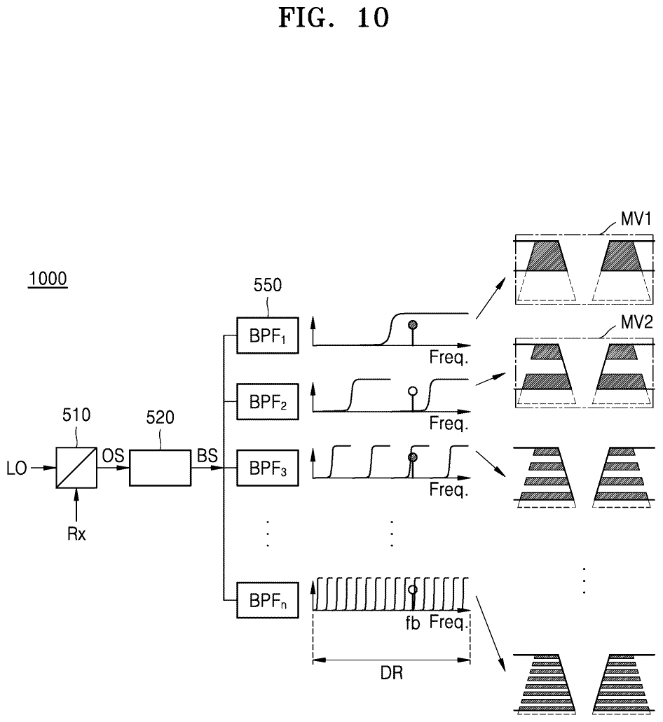

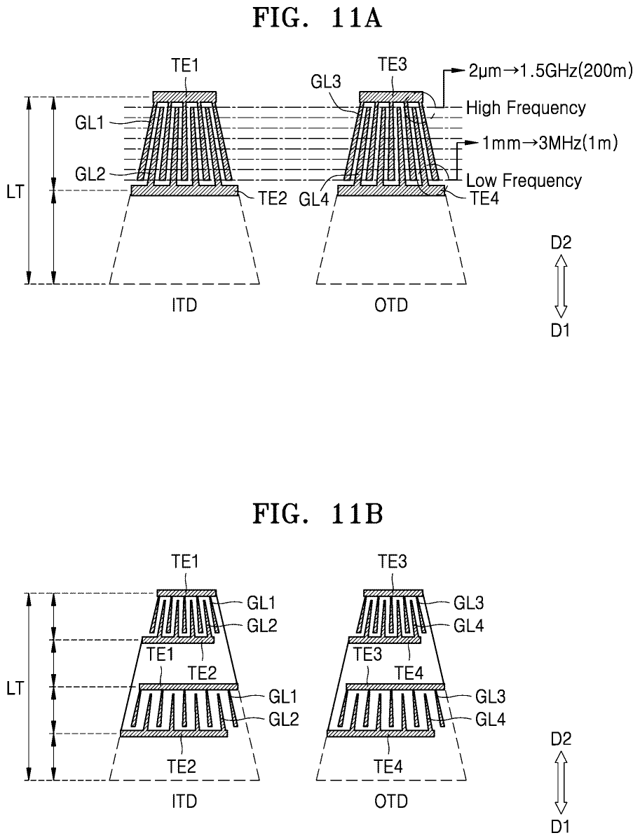

FIG. 9 is a schematic view for describing a surface acoustic wave filter. FIG. 10 is a diagram for describing a frequency analysis method using a surface acoustic wave filter. FIG. 11A is an enlarged view of a first region of FIG. 10, and FIG. 11B is an enlarged view of a second region of FIG. 10. In this case, the first region refers to MV1 of FIG. 10, and the second region refers to MV2 of FIG. 10.

The embodiment illustrated in FIG. 10 differs from the embodiment of FIG. 7 in that the band pass filter array 550 which is implemented by using a surface acoustic wave filter, only differs from the band pass filter array 540 which is implemented by using the band pass filter groups BPFG1, BPFG2, BPFG3, . . . , and BPFGn, but the remaining components of FIG. 10 are substantially the same as those of FIG. 7.

Referring to FIG. 9, the surface acoustic wave filter SAW may include a substrate SUB, an input transducer ITD, and an output transducer OTD. In this case, the substrate SUB may be a substrate made of a piezoelectric material. The substrate SUB may include various piezoelectric ceramic materials, but it is preferable that the characteristic change according to temperature is low.

The surface acoustic wave filter SAW is two transducers for transmission and reception consisting of a comb-shaped inter digital array of thin metal electrodes on the substrate SUB and may include an input transducer ITD and an output transducer OTD.

When the comb-shaped inter digital array is misaligned on the surface of the piezoelectric substrate SUB, the input electrical signal (e.g., beating signal BS) is converted to generate surface elastic waves, and only a specific frequency that is synchronized with the frequency of the surface acoustic wave may pass and the remaining frequencies may be attenuated. The surface acoustic wave filter SAW has the advantage of having a very sharp skirt characteristic compared to a small structure. The frequency characteristics of the surface acoustic wave filter SAW may be determined by the shape of the electrode pattern of the input transducer ITD and the output transducer OTD.

Referring to FIG. 10, the LiDAR system 1000 according to one or more embodiment may include an optical coupler 510, a photodiode 520, and a band pass filter array 550 to analyze the frequency in an analog signal state before converting the beating signal BS into a digital signal.

In this case, the optical coupler 510 of FIG. 10 may correspond to the second optical coupler 230 of FIG. 3, and the photodiode 520 of FIG. 10 may correspond to the balanced photodiode 241 of FIG. 3. In addition, in FIG. 10, for convenience of explanation, the transimpedance amplifier TIA of FIG. 3 is omitted between the photodiode 520 and the band pass filter array 530.

The optical coupler 510 may generate an optical signal (or the output signal OS of FIG. 3) by mixing the local oscillator signal LO with the reception signal Rx in which the local oscillator signal LO is reflected and returned from a target. The photodiode 520 may convert an optical signal (or the output signal OS of FIG. 3) into a beating signal BS. The beating signal BS may be an analog electrical signal.

The band pass filter array 550 may filter the beating signal BS to extract a beating frequency fb. The band pass filter array 550 may include a plurality of band pass filters BPF1, BPF2, BPF3, . . . , and BPFn, each having a plurality of pass bands that are repeated at a preset period.

The repetition period of the pass band of each of the band pass filters BPF1, BPF2, BPF3, . . . , and BPFn may be different. According to one or more embodiment, a period of the pass band of the n-th band pass filter BPFn may be DR/2ⁿ⁻¹. For example, the period of the pass band of the first band pass filter BPF1 may be DR, the period of the pass band of the second band pass filter BPF2 may be DR/2, and the period of the pass band of the third band pass filter BPF3 may be DR/4.

The band pass filter array 550 may include a plurality of band pass filters BPF1, BPF2, BPF3, . . . , and BPFn connected in parallel with each other. Each of the band pass filters BPF1, BPF2, BPF3, . . . , and BPFn may include the surface acoustic wave filter SAW of FIG. 9.

For example, referring to FIGS. 9 to 11B, each of the band pass filters BPF1, BPF2, BPF3, . . . , and BPFn may include a surface acoustic wave filter SAW including an input transducer ITD and an output transducer OTD having the same shape arranged on the substrate SUB.

The input transducer ITD may include a plurality of pairs of first transducer electrodes TE1 and second transducer electrodes TE2. Each of the first transducer electrodes TE1 may include a plurality of first group lines GL1 extending radially in a first direction D1, and each of the second transducer electrodes TE2 may include a plurality of second group lines GL2 extending counter radially in the second direction D2 and alternately arranged with the first group lines GL1.

Likewise, the output transducer OTD may include a plurality of pairs of third transducer electrodes TE3 and fourth transducer electrodes TE4. Each of the third transducer electrodes TE3 may include a plurality of third group lines GL3 extending radially in the first direction D1, and each of the fourth transducer electrodes TE4 may include a plurality of fourth group lines GL4 extending counter radially in the second direction D2 and alternately arranged with the third group lines GL3.

The gaps between the first group lines GL1 and the second group lines GL2 may increase in the first direction D1, and similarly, the gaps between the third group lines GL3 and the fourth group lines GL4 may also increase in the first direction D1.

The widths of the first group lines GL1 and the third group lines GL3 may increase in the first direction D1, and the widths of the second group lines GL2 and the fourth group lines GL4 may decrease in the second direction D2.

The distance of each of the input transducer ITD and the output transducer OTD in first direction D1 may correspond to the frequency search range DR of FIG. 10. Therefore, when the number of frequency levels is m, the number of pairs of the first transducer electrode TE1 and the second transducer electrode TE2 may be m/2.

For example, when there is only the first band pass filter BPF1 in FIG. 10, the number of frequency levels is 2, and thus the number of pairs of the first transducer electrodes TE1 and the second transducer electrodes TE2 may be one in each of the input transducer ITD and the output transducer OTD of the first band pass filter BPF1, as shown in FIG. 11A.

Meanwhile, when the first band pass filter BPF1 and the second band pass filter BPF2 are present in FIG. 10, the number of frequency levels is 4, and thus as shown in FIG. 11A, the number of pairs of the first transducer electrodes TE1 and the second transducer electrodes TE2 in each of the input transducer ITD and the output transducer OTD of the first band pass filter BPF1 is one, and as shown in FIG. 11B, the number of pairs of the first transducer electrodes TE1 and the second transducer electrodes TE2 in each of the input transducer ITD and the output transducer OTD of the second band pass filter BPF2 may be two.

The pairs of the first transducer electrodes TE1 and the second transducer electrodes TE2 may be formed only in the odd equally divided region when a length LT of each of the input transducer ITD and the output transducer OTD in the first direction D1 is equally divided into 2^{p}. In this case, p is a natural number. For example, when looking at the second band pass filter BPF2, the second band pass filter BPF2 has a frequency level of 4, and correspondingly, when the length LT is equally divided into quarters (i.e., p=2), pairs of the first transducer electrodes TE1 and the second transducer electrodes TE2 may be formed only in the first and third equally divided regions.

As such, in the surface acoustic wave filter SAW, the pass band of the band pass filter may be determined through the width between the first transducer electrode TE1 and the second transducer electrode TE2 (or the width between the third transducer electrode TE3 and the fourth transducer electrode TE4). When pairs of the first transducer electrodes TE1 and the second transducer electrodes TE2 (or the third transducer electrodes TE3 and the fourth transducer electrodes TE4) have a shape in which the width between the electrodes is continuously changed in a trapezoidal shape, the pass band may function as a band pass filter with wide characteristics. In this case, the band pass filters having a plurality of pass bands repeated at a preset period may be implemented by connecting pairs of a plurality of trapezoidal first transducer electrodes TE1 and a plurality of trapezoidal second transducer electrodes TE2 (or third transducer electrodes TE3 and fourth transducer electrodes TE4) in series.

For example, when describing the implementation of an FMCW LiDAR system with a chirp bandwidth of 1.5 GHZ, which measures a distance of up to 200 meters, in the case where the propagation sound speed of the substrate SUB is about 3 km/s, a 3 MHz frequency component may correspond to a distance of a 1 mm width between the first and second transducer electrodes TE1 and TE2 (or the third and fourth transducer electrodes TE3 and TE4), and a 1.5 MHz frequency component may correspond to a distance of a 2 μm width between the first and second transducer electrodes TE1 and TE2 (or the third and fourth transducer electrodes TE3 and TE4). That is, a band pass filter with a predetermined periodicity may be implemented by connecting pairs of trapezoidal first transducer electrodes TE1 and second transducer electrodes TE2 (or third transducer electrodes TE3 and fourth transducer electrodes TE4) of various sizes with a narrow electrode distance of about 2 μm or less and a wide electrode distance of about 1 mm or more.

The band pass filter array 550 has a preset frequency search range DR for extracting the beating frequency fb, and the frequency search range DR may be divided into a preset number of frequency levels (or distance level) based on measurable distance and distance resolution.

For example, as described above, in order for the LiDAR system 1000 to implement a measurable distance of 200 m and a distance resolution of 10 cm, about 2000 levels of distance component analysis corresponding to the value of 200 m divided by 10 cm may be required.

Like the frequency analysis method shown in FIG. 7, in the frequency analysis method shown in FIG. 10, the pass band of each band pass filter reflects each bit in the binarized value of the beating signal. For example, in a simple example provided with only the first pass band filter (BPF1) and the second pass band filter (BPF2) of FIG. 8, if the beating signal linearly increases in the direction from the lowest to the highest for the entire frequency search range DR, whether the first pass band filter (BPF1) passes and whether the second pass band filter (BPF2) passes may be confirmed and expressed as (0,0), (0,1), (1,0), and (1,1). That is, the pass signal of the first pass band filter BPF1 represents a 2-bit signal representing the most significant bit, and the pass signal of the second pass band filter BPF2 represents a 2-bit signal representing the least significant bit. (to WC: please check)

In other words, when the number of band pass filters BPF1, BPF2, BPF3, . . . , and BPFn is n, the number of frequency levels may be determined to be 2ⁿ. Therefore, 11 band pass filters BPF1, BPF2, BPF3, . . . , and BPFn may be required for distance component analysis of 2000 levels.

Meanwhile, in FIG. 10, the band pass filters BPF1 to BPFn are implemented as surface acoustic wave filters, but are not limited thereto. For example, the band pass filters BPF1 to BPFn may include any one of an electrical circuit including a series and/or parallel combination of R, L, and C elements, and a volume acoustic wave filter.

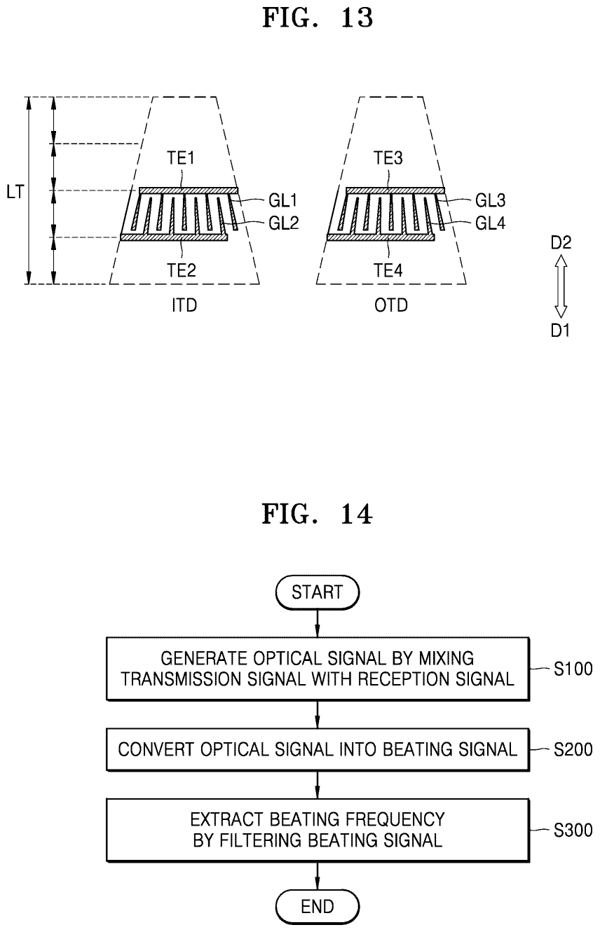

FIG. 12 is a diagram for describing a frequency analysis method according to one or more embodiment. FIG. 13 is an enlarged view of a third region of FIG. 12. In this case, the third region refers to MV3 in FIG. 12.

The embodiment illustrated in FIG. 12 differs from the embodiment illustrated in FIG. 10, only in the shape of the input transducer ITD and the shape of the output transducer OTD, but the remaining components are substantially the same.

Referring to FIG. 12, the LiDAR system 1000 according to one or more embodiment may include an optical coupler 510, a photodiode 520, and a band pass filter array 560 to analyze the frequency in an analog signal state before converting the beating signal BS into a digital signal.

In this case, the optical coupler 510 of FIG. 12 may correspond to the second optical coupler 230 of FIG. 3, and the photodiode 520 of FIG. 12 may correspond to the balanced photodiode 241 of FIG. 3. In addition, in FIG. 12, for convenience of explanation, the transimpedance amplifier TIA of FIG. 3 is omitted between the photodiode 520 and the band pass filter array 530.

The optical coupler 510 may generate an optical signal (or the output signal OS of FIG. 3) by mixing the local oscillator signal LO with the reception signal Rx in which the local oscillator signal LO is reflected and returned from a target. The photodiode 520 may convert an optical signal (or the output signal OS of FIG. 3) into a beating signal BS. The beating signal BS may be an analog electrical signal.

The band pass filter array 560 may filter the beating signal BS to extract a beating frequency fb. The band pass filter array 560 may include a plurality of band pass filters BPF1, BPF2, BPF3, . . . , and BPFn having different pass bands and different bandwidths. The plurality of band pass filters BPF1, BPF2, BPF3, . . . , and BPFn may be connected in parallel with each other.

Each of the band pass filters BPF1, BPF2, BPF3, . . . , and BPFn may include the surface acoustic wave filter SAW of FIG. 9.

For example, referring to FIG. 12, each of the band pass filters BPF1, BPF2, BPF3, . . . , and BPFn may include a surface acoustic wave filter SAW including an input transducer ITD and an output transducer OTD having the same shape arranged on the substrate SUB.

Referring to FIG. 13, the input transducer ITD may include a plurality of pairs of first transducer electrodes TE1 and second transducer electrodes TE2. Each of the first transducer electrodes TE1 may include a plurality of first group lines GL1 extending radially in a first direction D1, and each of the second transducer electrodes TE2 may include a plurality of second group lines GL2 extending counter radially in the second direction D2 and alternately arranged with the first group lines GL1.

Likewise, the output transducer OTD may include a plurality of pairs of third transducer electrodes TE3 and fourth transducer electrodes TE4. Each of the third transducer electrodes TE3 may include a plurality of third group lines GL3 extending radially in the first direction D1, and each of the fourth transducer electrodes TE4 may include a plurality of fourth group lines GL4 extending counter radially in the second direction D2 and alternately arranged with the third group lines GL3.

As described above, in the band pass filter array 550 of FIG. 10, pairs of the first transducer electrodes TE1 and the second transducer electrodes TE2 are formed only in the odd regions when the length LT of each of the input transducer ITD and the output transducer OTD in the first direction D1 is equally divided into 2^{p}. For example, when looking at the second band pass filter BPF2, the second band pass filter BPF2 has a frequency level of 4, and correspondingly, when the length LT is equally divided into quarters (i.e., p=2), pairs of the first transducer electrodes TE1 and the second transducer electrodes TE2 may be formed only in the first and third equally divided regions.

Meanwhile, in the band pass filter array 560 of FIG. 12, pairs of the first transducer electrodes TE1 and the second transducer electrodes TE2 are formed only in a 2^{p-1} region when the length LT of each of the input transducer ITD and the output transducer OTD in the first direction D1 is equally divided into 2^{p}. For example, when looking at the second band pass filter BPF2, the second band pass filter BPF2 has a frequency level of 4, and correspondingly, when the length LT is equally divided into quarters (i.e., p=2), pairs of the first transducer electrodes TE1 and the second transducer electrodes TE2 may be formed only in the third equally divided region. In this case, for convenience of explanation, the embodiments in which the length LT of each of the input transducer ITD and the output transducer OTD in first direction D1 is divided at equal intervals to form pairs of the first transducer electrodes TE1 and the second transducer electrodes TE2 have been described in FIGS. 10 and 12, but embodiments are not limited thereto. For example, according to design needs, the length LT of each of the input transducer ITD and output transducer OTD in first direction D1 may be divided into unequal intervals to form pairs of the first transducer electrodes TE1 and the second transducer electrodes TE2.As described above, when the band pass filters BPF1 to BPFn of FIG. 12 are similar to the band pass filters BPF1 to BPFn of FIG. 10 but the transducer electrodes TE1 to TE4 are formed at different positions, band pass filters BPF1 to BPFn having different pass bands and different bandwidths may be implemented.

In this case, n frequency levels (or distance levels) may be expressed by using n band pass filters, but each frequency level may not be equidistant. For example, a distance of 0 m to 200 m may be measured in four levels: 0 m to 1 m; 1 m to 10 m; 10 m to 100 m; and 100 m to 200 m. In this case, the distance resolution may be low in the long-distance measurement, but the distance resolution may be high in the short-distance measurement. As described above, since measuring distance and/or speed by frequency analysis in the FMCW LiDAR system 1000 requires a lot of computing resources, implementing a distance resolution which is not linear according to the distance may be an alternative.

In each of the surface acoustic wave filters shown in FIG. 12, portions in which the transducer electrode pairs are formed may have pass bandwidths at unequal intervals, as in graphs indicated by thick solid lines in the band pass filters BPF1 to BPFn, respectively. As shown in FIG. 12, when each of the band pass filters BPF1 to BPFn is formed, n distance leveling may be performed in which a distance resolution degrades to ½ as a distance to a target increases.

Meanwhile, in a short-distance zone where high distance resolution is required, the distance is detected by using a conventional frequency analysis method (a method of performing digital signal conversion and calculation after frequency domain conversion). In a long-distance zone requiring a relatively low distance resolution, it may be implemented to detect a distance by using a method of directly analyzing frequencies in the analog signal state described through the embodiments shown in FIGS. 5, 7, 10, and 12.

As described above, a combination of a conventional frequency analysis method including a frequency analysis method through binarization and fast Fourier transform for the entire measurable interval, and a method of directly analyzing the frequency in the analog signal state described through the embodiments shown in FIGS. 5, 7, 10, and 12 may be possible. This may be utilized for reasonable distance and/or speed detection within limited computing resources, and the quantified results of each channel (or band pass filter) obtained from each frequency analysis method are input to a neural network, etc. to be used for detection of distance and/or speed.

Meanwhile, in FIG. 12, the band pass filters BPF1 to BPFn are implemented as surface acoustic wave filters, but are not limited thereto. For example, the band pass filters BPF1 to BPFn may include any one of an electrical circuit including a series and/or parallel combination of R, L, and C elements, and a volume acoustic wave filter.

FIG. 14 is a flowchart for describing a frequency analysis method according to one or more embodiment. In this case, the components of the present disclosure described with reference to FIGS. 1 to 13, which are not explicitly shown in FIG. 14, may be applied to the frequency analysis method.

Referring to FIGS. 1 to 14, an operating method of a LiDAR system according to one or more embodiment may include an operation S100 of generating an optical signal (or an output signal OS) by mixing an local oscillator signal LO with a reception signal Rx in which the local oscillator signal LO is reflected and returned from a target by the optical coupler 510, an operation S200 of converting the optical signal (or the output signal OS) into an analog beating signal BS by the photodiode 520, and an operation S300 of filtering the beating signal BS and extracting a beating frequency fb by each of the band pass filter arrays 530, 540, 550, and 560.

The operating method of a LiDAR system according to one or more embodiment may include an operation of calculating, by the controller (or the analog processor 330 of the control circuit 300), a distance and/or speed with respect to a target based on the beating frequency fb.

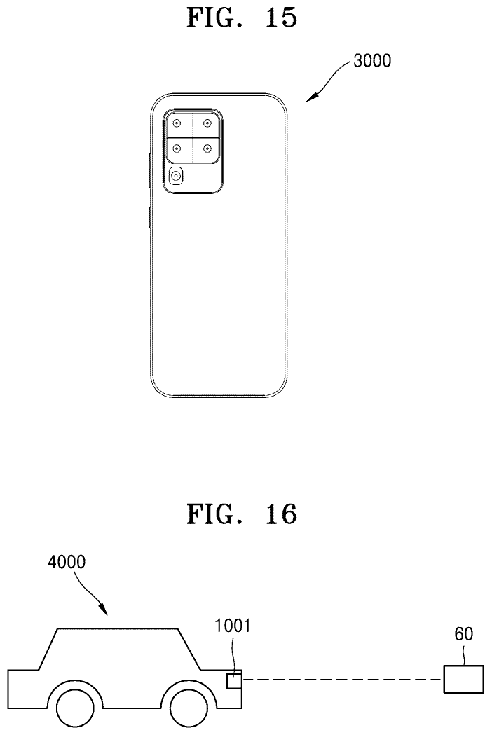

FIG. 15 is a perspective view showing an electronic device to which a LIDAR system according to one or more embodiment is applied.

FIG. 15 is illustrated in the form of a mobile phone or a smart phone 3000, but the electronic device to which the LiDAR system is applied is not limited thereto. For example, it may be applied to tablets or smart tablets, laptop computers, televisions, or smart televisions.

In addition, the LiDAR system according to one or more embodiment may be applied to an autonomous driving device.

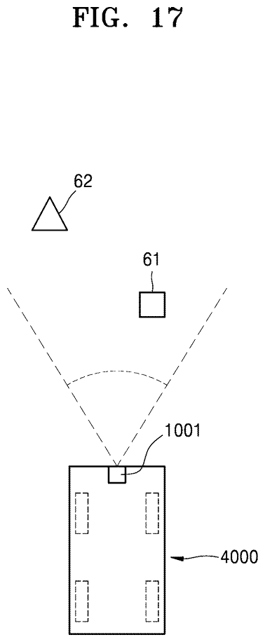

FIGS. 16 and 17 are conceptual views illustrating a case in which a LIDAR system according to one or more embodiment is applied to a vehicle, and are a side view and a top view, respectively.

Referring to FIG. 16, a LiDAR system 1001 may be applied to a vehicle 4000, and information on a subject 60 may be obtained by using the LiDAR system 1001. The LiDAR system 1001 may employ the LiDAR system described with reference to FIGS. 2 to 14. The vehicle 4000 may be a vehicle having an autonomous driving function. As described in FIG. 16, the LiDAR system 1001 may divide a target area of a target field of view into a plurality of sub-areas and irradiate a set of beams split one by one in the plurality of sub-areas at predetermined time intervals. When a subject is in the target area and light reflected therefrom is detected, a digital scan of the target area may be started and information on the subject 60 may be analyzed. By using the LiDAR system 1001, the vehicle 4000 may detect objects or people, such as the subject 60, in its travel direction. The distance to the subject 60 may be measured using information such as a time difference between the transmission and reception of a signal. In addition, as shown in FIG. 17, it is possible to obtain information on the subject 61 nearby within the target area and the subject 62 positioned farther away within the same target area.

Although FIGS. 16 and 17 illustrate that a LIDAR system is applied to a vehicle, embodiments are not limited thereto. The LiDAR system may be applied to aircraft such as drones, mobile devices, small walking means (e.g., bicycles, motorcycles, strollers, boards, etc.), robots, human/animal aids (e.g., wands, helmets, jewelry, clothing, watches, bags, etc.), Internet of Things (IoT) devices/systems, security devices/systems, etc.

The above-described LiDAR system has been described with reference to the embodiments shown in the drawings. According to a LIDAR system and an operating method of the same according to embodiments, it is possible to reduce computing resources required for frequency analysis by passing an analog beating signal through a band pass filter to extract a beat frequency.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A light detection and ranging (LiDAR) system comprising:
an optical coupler configured to generate an optical signal by mixing a transmission signal with a reception signal, in which the transmission signal is reflected back from a target;
a photodiode configured to convert the optical signal into an analog beating signal; and
a band pass filter array configured to filter the analog beating signal to extract a beating frequency.

2. The LiDAR system of claim 1, further comprising a control circuit configured to calculate at least one of a distance to the target and a speed of the target based on the beating frequency.

3. The LiDAR system of claim 1, further comprising an analog-to-digital converter configured to convert the filtered analog beating signal into a digital signal by sampling and quantizing the filtered beating signal.

4. The LiDAR system of claim 1, wherein the band pass filter array comprises a plurality of band pass filters having different pass bands.

5. The LiDAR system of claim 4, wherein the band pass filter array is configured to have a preset frequency search range for extracting the beating frequency, wherein the frequency search range is divided into a preset number of frequency levels based on a measurable distance and a distance resolution, and when the number of band pass filters is n, the number of frequency levels is determined to be n.

6. The LiDAR system of claim 4, wherein the band pass filter array comprises the plurality of band pass filters connected in parallel with each other.

7. The LiDAR system of claim 6, wherein the plurality of band pass filters are electric circuits including a series and parallel combination of a resistor, an inductor, and a capacitor.

8. The LiDAR system of claim 1, wherein the band pass filter array comprises a plurality of band pass filter groups, and
wherein each of the plurality of band pass filter groups has a plurality of pass bands repeated at a preset period.

9. The LiDAR system of claim 8, wherein the band pass filter array has a preset frequency search range for extracting the beating frequency,
wherein the frequency search range is divided into a preset number of frequency levels based on a measurable distance and a distance resolution, and when the number of band pass filter groups is n, the number of frequency levels is determined to be 2ⁿ.

10. The LiDAR system of claim 8, wherein
the band pass filter array comprises the plurality of band pass filter groups connected in parallel with each other, and
each of the plurality of band pass filter groups comprises a plurality of band pass filters connected in parallel with each other.

11. The LiDAR system of claim 10, wherein the plurality of band pass filters are electric circuits including a series and parallel combination of a resistor, an inductor, and a capacitor.

12. The LiDAR system of claim 1, wherein the band pass filter array comprises a plurality of band pass filters,
wherein each of the plurality of band pass filters has a plurality of pass bands repeated at a preset period, and has a preset frequency search range for extracting the beating frequency, and
wherein the frequency search range is divided into a preset number of frequency levels based on a measurable distance and a distance resolution.

13. The LiDAR system of claim 12, wherein
each of the plurality of band pass filters comprises a surface acoustic wave filter comprising an input transducer and an output transducer,
the input transducer comprises a plurality of pairs of first transducer electrodes and second transducer electrodes,
each of the first transducer electrodes comprises a plurality of first group lines extending radially in a first direction, and each of the second transducer electrodes comprises a plurality of second group lines extending counter-radially in a second direction and alternately arranged with the first group lines,
the output transducer comprises a plurality of pairs of third transducer electrodes and fourth transducer electrodes, and
each of the third transducer electrodes comprises a plurality of third group lines extending radially in the first direction, and each of the fourth transducer electrodes comprises a plurality of fourth group lines extending counter radially in the second direction and alternately arranged with the third group lines.

14. The LiDAR system of claim 13, wherein
a gap between the first group lines and the second group lines increases in the first direction, and
a gap between the third group lines and the fourth group lines increases in the first direction.

15. The LiDAR system of claim 14, wherein
widths of the first group lines and the third group lines increase in the first direction, and
widths of the second group lines and the fourth group lines decrease toward the second direction.

16. The LiDAR system of claim 13, wherein
a distance of each of the input transducer and the output transducer in the first direction corresponds to the frequency search range, and
when the number of frequency levels is m, the number of pairs of the first transducer electrodes and the second transducer electrodes is m/2.

17. The LiDAR system of claim 16, wherein the pairs of the first transducer electrodes and the second transducer electrodes are formed only in odd-numbered equal division areas when a length of each of the input transducer and the output transducer in the first direction is equally divided into 2^{p}, where p is a natural number.

18. The LiDAR system of claim 16, wherein the pairs of the first transducer electrodes and the second transducer electrodes are formed only in a division area equally divided into 2^{p-1} when a length of each of the input transducer and the output transducer in the first direction is equally divided into 2^{p}, where p is a natural number.

19. An operating method of a light detection and ranging (LiDAR) system, the operating method comprising:
generating an optical signal by mixing a transmission signal with a reception signal, in which the transmission signal is reflected back from a target;
converting the optical signal into an analog beating signal;
extracting, by a band pass filter array, a beating frequency by filtering the analog beating signal; and
calculating at least one of a distance to the target and a speed of the target based on the beating frequency.

20. A vehicle comprising:
an optical coupler configured to obtain an optical signal by mixing a transmission signal to be transmitted to a target, with a reception signal that is received when the transmission signal is reflected back from the target;
a focal plane array configured to convert the optical signal into an analog beating signal; and
a plurality of band pass filters configured to receive the analog beating signal and pass a plurality of different frequency bands of the analog beating signal to extract a beating frequency from at least one of the plurality of different frequency bands.
